(19) United States
(12) Patent Application Publication
(10) Pub. No.: US 2008/0088004 A1
(43) Pub. Date: Apr. 17, 2008

(54) WAFER LEVEL PACKAGE STRUCTURE WITH BUILD UP LAYERS

(75) Inventors: Wen-Kun Yang, Hsinchu City (TW); Chao-Nan Chou, Taipei City (TW); Ching-Shun Huang, Chigtong Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/549,985

(22) Filed: Oct. 17, 2006

(51) Int. Cl. H01L 23/48

(52) U.S. Cl. 257/690; 257/738; 257/779

(57) ABSTRACT

The present invention discloses a structure of wafer level packaging. To use the elastic materials with low k dielectric constant and larger elongation properties as dielectric layers materials used for build up layers of semiconductor device packaging, it can improve the reliability, especially in the board level temperature cycling test. In principle, the elastic dielectric layers can absorb the stress due to CTE (Coefficient of Thermal Expansion) mismatching issue.

### FIELD OF THE INVENTION

This invention relates to a wafer level package, and more particularly to a wafer level package structure with elastic dielectric layers in build up layers process, the wafer level package structure can avoid the open circuit caused by the solder ball cracking due to the temperature variation inducing the reinforcing stress between the solder balls and a print circuit board.

### BACKGROUND OF THE INVENTION

### Description of the Prior Art

The earlier lead frame package technology is already not suitable for the advanced semiconductor dice due to the density of the terminals thereof is too high. Hence, a new package technology of BGA (Ball Grid Array) has been developed to satisfy the packaging requirement for the advanced semiconductor dice. The BGA package has an advantage of that the spherical terminals has a shorter pitch than that of the lead frame package, and the terminals of the BGA are unlikely to be damage and deform. In addition, the shorter signal transmitting distance benefits to raise the operating frequency to conform to the requirement of faster efficiency. Most of the package technologies divide dice on a wafer into respective dice and then to package and test the die respectively. Another package technology, called “Wafer Level Package (WLP)”, can package the dice on a wafer before dividing the dice into respective individual die. The WLP technology has some advantages, such as a shorter producing cycle time, lower cost, and no need to under-fill or molding.

Moreover, the chip is trending to small size and high density (having lots of terminals) for CSP (chip scale package) or FC (flip chip) package. Therefore, the intervals between adjacent contacts of a die are evolved to become very small, resulting in difficulty of planting the solder balls and causing the problem of surface mounting fail. Accordingly, the reliability and yield of semiconductor packages would decrease greatly, and the technology of CSP or FC package is unable to be worked out. In order to solve the problems mentioned above, a semiconductor package is brought up from U.S. Pat No. 6,271,469 entitled “direct build-up layer on an encapsulated die package”.

In chip packaging technology, the active surface of the die is subject to numerous electrical couplings that are usually brought to the edge of the chip package. Heat generation is significant at the active surface of the die, and consequently at the pin-out locations of the chip package. Electrical connections, referred to variously as bond wires, balls, bumps, and others, are connected to terminals on the active surface of a chip. The connections include solders and/or plastics that make mechanical connections and electrical couplings to a substrate. If the connections are solder bumps, the solder bumps on the flip-chip are soldered to the bonding pads on the substrate. In flip-chip packages, a gap exists between the flip-chip active surface and the mounting substrate. One characteristic of flip-chip technology is shear stress on the solder joints during temperature cycling of the device. This shear stress is partially a result of a difference in the CTE of the flip-chip and the mounting substrate.

Besides, a chip package structure is shown as FIG. 1. The package structure comprises a dielectric layer 105 covering a chip 100 on a wafer 101. The material of the dielectric layer 105 may be BCB, polyimides (PI). The redistribution layer (RDL) trace 102 is formed on the chip 100 via an inter-connecting metal 103 to electrically connected I/O pads 104 of the chip 100. The redistribution layer trace 102 is formed on the inter-connecting metal 103 by removing selected portions of the metal redistribution layer according to well known photolithography techniques.

Next, an isolation layer 106 covers the redistribution layer (RDL) 102 for a plurality of openings formed thereon by removing selected portions of the isolation layer 106 according to a photolithography process. Each of the openings has a solder ball 107 to electrically couple with a print circuit board or external parts. The material of the isolation layer 106 may be a dielectric layer such as BCB or polyimides (PI) with CTE about 50 (ppm/° C.) and elongation about 10%, hardness same as properties of plastic materials,

The aforementioned wafer level package structure generally needs an additional material to intensify the solder ball 107. Moreover, the redistribution layer (RDL) 102 may be stuck at the dielectric layer 105 due to using the high power sputtering process to form the seed metal layers and thereby creating a good adhesion between the redistribution layer (RDL) 102 and the dielectric layer 105, which is drawback to the solder ball. The solder metal may be formed a solder ball 107 connected with the redistribution layer (RDL) 102 through the UBM structure (do not shows on the drawing) after IR reflow. When the solder ball 107 joints to the print circuit board, the stress may be induced by temperature influence at the joint part between the solder ball 107 and the redistribution layer (RDL) 102, the solder ball 107 will be cracked owing to reinforcing stress raised by temperature variation (cycling), thereby causing open circuit between the solder ball and metal pad. As shown in FIG. 2, a shear arm 202 is applied to the solder ball shear test (the way to identify the solder join strength between solder ball and solder metal pad). When a solder ball 204 formed on a solder metal pad 203 is pushed by the shear arm 202, the solder ball 204 will be pushed out of the original position owing to strong adhesion between the solder metal pad 203 and a BCB/PI based dielectric layer 201. In other words, the failure mode of board level temperature cycling test or ball shear test are solder creaking either in chip site or PCB site.

In view of the aforementioned, the present invention provides an improved wafer level package structure to overcome the above drawback.

### SUMMARY OF THE INVENTION

It is an objective of the present invention to provide a wafer level or chip size package structure with build up layers. The wafer level package structure of the present invention can avoid open circuit due to solder ball cracking by an external force or high temperature thermal stress.

The present invention provides a wafer level or chip size package structure. The package structure comprises build up layers made of elastic dielectric layers; and conductive layer configured with said build up layers and coupled to a chip; wherein the conductive layer is formed by employing lower power in sputtering seed metal layers process to gain a poor adhesion between the conductive layer and the elastic dielectric layer than that between the conductive layer and solder balls of an external part.

To use the silicone based materials with low k dielectric constant and CTE (Coefficient of Thermal Expansion) larger than 100 ppm/° C.), elongation about 40% (preferably 30˜50%) for build up layers of semiconductor device packaging, it can improve the reliability, especially in the board level temperature cycling test owing to the deformation of elastic dielectric and the poor adhesion between the redistribution layer and the elastic dielectric layer.

The chip is an IC (Integrated Circuit) device. The elastic dielectric layer has the properties of CTE greater than 100 (ppm/° C.) and elongation about 40%, preferably 30%˜50%. The elastic dielectric layers comprise multiple silicone based dielectric layers. The conductive layer comprises redistribution metal layer, and the redistribution metal layer includes Ti/Cu/Au alloy or Ti/Cu/Ni/Au alloy. The external part comprises print circuit board.

The package structure further comprises an adhesive layer surrounding the chip, and further comprises a rigid substrate which the adhesive layer and the chip are formed thereon.

### BRIEF DESCRIPTION OF THE DRAWINGS

The above objects, and other features and advantages of the present invention will become more apparent after reading the following detailed description when taken in conjunction with the drawings, in which:

FIG. 1 is a schematic diagram of a conventional wafer level package structure.

FIG. 2 is a schematic diagram of a solder ball shear test structure.

FIG. 3 is a schematic diagram of a wafer level package structure with build up layers according to the present invention.

FIG. 4 is a schematic diagram of a fan-out wafer level package structure with build up layers according to the present invention.

FIG. 5 is a schematic diagram of a solder ball shear test in early testing stage.

FIG. 6 is a schematic diagram of a solder ball shear test in final testing stage.

FIG. 7 is a schematic diagram of a chip size package structure with build up layers according to the present invention.

FIG. 8 is a schematic diagram of a chip size package structure with build up layers in external force applied or high temperature condition according to the present invention.

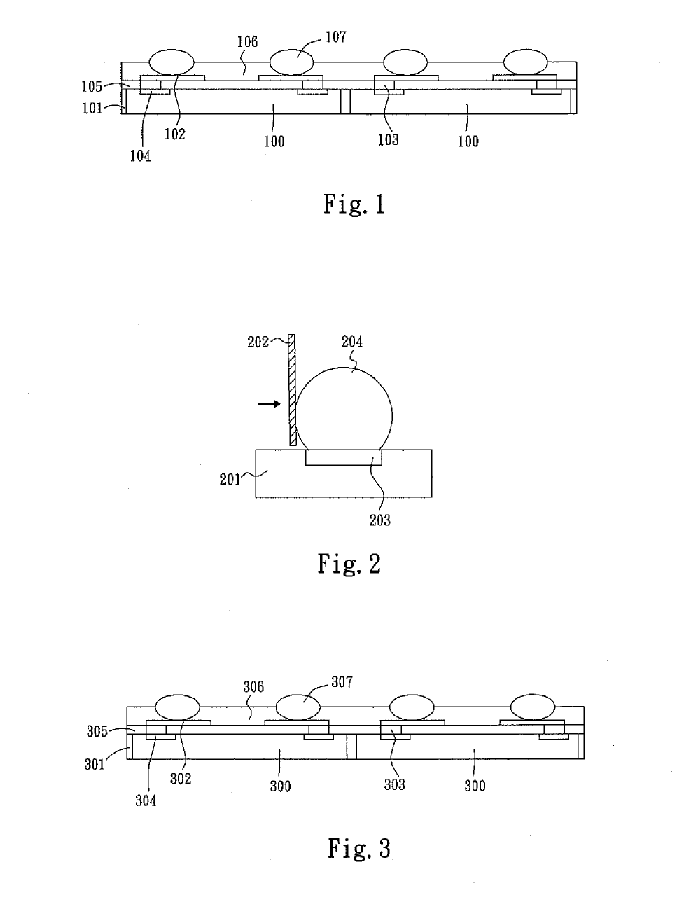

### DESCRIPTION OF THE PREFERRED EMBODIMENT

The present invention provides a backend structure of wafer level packaging, and the scope of the present invention is expressly not limited expect as specified in the accompanying claims. The present invention discloses a structure of wafer level packaging that use the silicone based materials with low k dielectric constant and CTE (Coefficient of Thermal Expansion) larger than 100 (ppm/° C.), elongation about 40% (preferably 30˜50%), hardness between the properties of plastic and rubber materials used for build up layers of semiconductor device packaging, it can improve the reliability, especially in the board level temperature cycling test. In principle, the silicone based materials mentioned above can absorb the stress due to CTE (Coefficient of Thermal Expansion) mismatching issue.

As shown in FIG. 3, it depicts a wafer level packaging structure by using build up layers process according to the present invention. The wafer level packaging structure is expressly not limited expect as specified in the accompanying claims of the present invention. The package structure comprises a elastic dielectric layer 305 covering a chip 300 on a wafer 301. The material of the elastic dielectric layer 305 may be silicone based materials, such as SINR (Siloxane polymer), with CTE (Coefficient of Thermal Expansion) larger than 100 (ppm/° C.), elongation about 40% (preferably 30˜50%), hardness between the properties of plastic and rubber materials. The redistribution layer (RDL) trace 302 is formed on the chip 300 via an inter-connecting metal layer 303 to electrically connected I/O pads 304 of the chip 300. The redistribution layer trace 302 is formed on the inter-connecting metal 303 and the dielectric layer 305 by removing selected portions of the metal redistribution layer according to well known photolithography techniques. The thickness of the silicone based elastic dielectric layer 305 is preferably from 3 um to 20 um, the thickness of elastic dielectric layer will depends on the stress strength of temperature cycling.

In one preferred embodiment, the material of the redistribution (RDL) 302 conductive layer includes Ti/Cu/Au alloy or Ti/Cu/Ni/Au alloy with a thickness of 5 to 25 micron. The Ti/Cu alloy may be formed by sputtering technique, and the Cu/Au or Cu/Ni/Au alloy may be formed by electroplating, wherein the thickness of said metal alloy is preferred around 5˜20 micron. The material of the metal pads 304 may be Al or Cu or the combination. Using the electro-plating process to make the redistribution layer metal trace 302, it allowed the much thickness metal that allow to against the stress due to CTE mismatching in temperature cycling.

Next, another dielectric layer 306 is formed on the dielectric layer 305 to cover the redistribution layer 302 and a plurality of openings formed thereon by removing selected portions of the dielectric layer 306 according to a photolithography process. Each of the openings has a contact metal ball (solder ball) 307 to electrically couple with a print circuit board or external parts (UBM structure does not show in the drawing). In one embodiment, the material of the dielectric layer 306 may be silicone based materials, such as SINR (Siloxane polymer), with CTE (Coefficient of Thermal Expansion) larger than 100 (ppm/° C.), elongation about 40% (preferably 30˜50%), hardness between the properties of plastic and rubber materials. The thickness of the silicone based dielectric layer 306 on the redistribution metal layer is preferably from 10 um to 50 um, and the thickness of the silicone based dielectric layer 306 under the redistribution metal layer is above 3 micron.

Moreover, the redistribution layer 302 may be adhesive at the silicone based elastic dielectric layer 305 by using the lower power sputtering process to form the seed metal layers (Ex. Ti/Cu) such that the adhesion between the seed metal layer and the elastic dielectric layer 305 is poor than the adhesion between the redistribution layer 302 and the solder metal join. In one embodiment, power density in sputtering seed metal layer process is preferably from 0.1 kW to 0.5 kW for pre-etching and from 1 kW to 4 kW for sputtering seed metal. The solder metal may be formed a solder ball 307 connected with the redistribution layer 302 after IR reflow. When the solder ball 307 soldering joints to the print circuit board, the stress may be induced by temperature influence at the joint part between the solder ball 307 and the redistribution layer 302, the solder ball 307 will be not cracked owing to the deformation property of the elastic dielectric layer 305 and the poor adhesion between the redistribution layer 302 and the elastic dielectric layer 305. In one embodiment, deformation ratio of the elastic dielectric layer is about 30% to 50%.

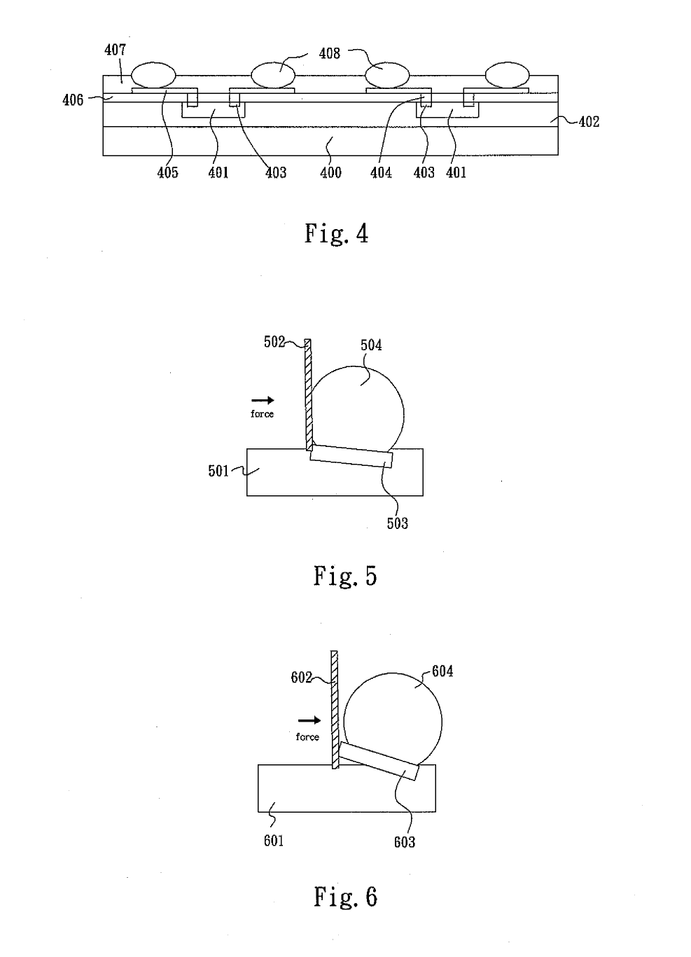

In another embodiment, as shown in FIG. 4, it depicts a fan-out wafer level packaging structure wit build up layers according to the present invention. The package structure comprises a chip 401 formed on a rigid substrate 400. For example, materials of the rigid substrate 400 comprise metal, glass, silicon, ceramic, FR4, FR5, BT, PI or PCB. Core paste 402 is formed on the rigid substrate 400 and filled into area between adjacent chip 401. A elastic dielectric layer 406 is formed on the core paste 402 to cover the chip 401 and a plurality of openings formed on metal pads 403 of the chip 401. The material of the elastic dielectric layer 406 may be silicone based materials, such as SINR (Siloxane polymer), with CTE (Coefficient of Thermal Expansion) larger than 100 (ppm/° C.), elongation about 40% (preferably 30˜50%). The redistribution layer trace 405 is formed on the chip 401 via an inter-connecting metal 404 to electrically connected I/O pads 403. The redistribution layer trace 405 is formed on the inter-connecting metal 404 and the elastic dielectric layer 406 by removing selected portions of the redistribution metal layer according to photolithography techniques.

Similarly, a dielectric layer 407 is formed on the dielectric layer 406 to cover the redistribution layer 405 and a plurality of openings formed thereon by removing selected portions of the dielectric layer 407 according to a photolithography process. Each of the openings has a contact metal ball (solder ball) 408 to electrically couple with a print circuit board or external parts. In one embodiment, the material of the dielectric layer 407 may be silicone based materials, such as SINR (Siloxane polymer), with CTE (Coefficient of Thermal Expansion) larger than 100 (ppm/° C.), elongation about 40% (preferably 30˜50%).

As the same, the redistribution layer 405 may be adhesive at the silicone based dielectric layer 406 by using the lower power sputter process to form the seed metal layer such that the adhesion between the seed metal layer and the dielectric layer 406 is poor than the adhesion between the redistribution layer 405 and the solder metal join. In one embodiment, power density in sputtering process is preferably from 0.1 kW to 0.5 kW for pre-etching and from 1 kW to 4 kW for sputtering metal. Solder ball 408 is connected with the redistribution layer 405 after IR reflow (UBM structure does not show on the drawing). When the solder ball 408 joints to the print circuit board, the stress may be induced by temperature influence at the joint part between the solder ball 408 and the redistribution layer 405, the solder ball 408 will be not cracked owing to the deformation property of elastic dielectric layer 406 and the poor adhesion between the redistribution layer 405 and the elastic dielectric layer 406. In one embodiment, deformation ratio of the elastic dielectric layer is about 30% to 50%.

As shown in FIG. 5, a shear arm 502 is applied to the solder ball shear test. When a solder ball 504 formed (soldering join) on a solder metal pad 503 is pushed by the shear arm 502, in early testing stage, the solder metal pad (for example, UBM on redistribution metal layer) 503 will be lifted owing to the silicone based dielectric layer 501 with elongation about 40% for de-formation certain degree, and poor adhesion between the solder metal pad 503 and the silicone based dielectric layer 501. In final testing stage, if the force through a shear arm 602 over the elongation utmost of the silicone based elastic dielectric layer 601, than a solder metal pad 603 coupled to a solder ball 604 will be peeling from the original position. Moreover, if the force through a shear arm 602 without over the elongation utmost of the silicone based elastic dielectric layer 601, after the shear arm releasing the force, than the solder metal pad 603 will be back return to the original position. In other words, in this embodiment, the failure mode of board level temperature cycling test or ball shear test are peeling from the solder metal pad (redistribution metal layer) 603 and the elastic dielectric layer 601, shown in FIG. 6. Such condition, the solder metal ball still connects to the redistribution metal layer even the solder metal pad 603 moving from the original position and thereby no electrical fail. According to the structure of the present invention, starting to shear solder ball such that the solder ball has leaved the original position (deformation property of elastic dielectric layer), and after the shear arm releasing the force, the solder ball can be returned to the same position if the shear distance does not over it.

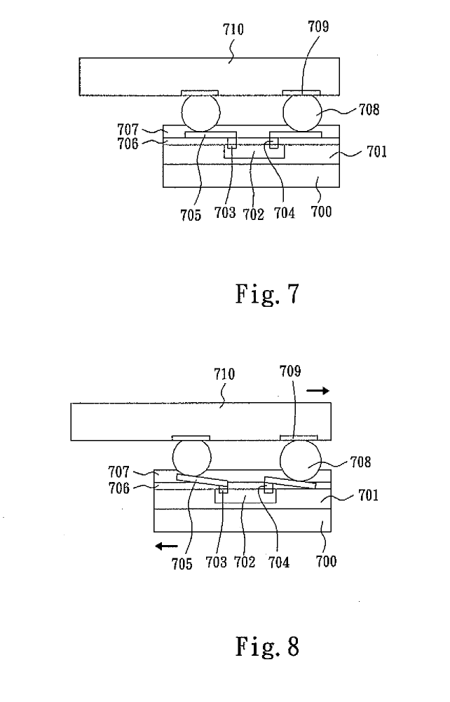

In yet another embodiment, as shown in FIG. 7, it depicts a chip size packaging structure with build up layers according to the present invention, wherein the solder balls 708 mounts to the print circuit board 710 via I/O pads 709. The chip size package structure comprises a chip 702 formed on a rigid substrate 700. Core paste 701 is formed on the rigid substrate 700 and filled into area between adjacent chips 702. An elastic dielectric layer 706 is formed on the core paste 701 to cover the chip 702 and a plurality of openings formed on metal pads 703 of the chip 702. The redistribution layer trace 705 is formed on the chip 703 via an inter-connecting metal 704 to electrically connected I/O pads 703. The redistribution layer trace 705 is formed on the inter-connecting metal 704 and the elastic dielectric layer 706.

Similarly, a dielectric layer 707 is formed on the dielectric layer 706 to cover the redistribution layer 705 and a plurality of openings formed thereon. Each of the openings has a contact metal ball (solder ball) 708 to electrically couple with a print circuit board or external parts 710.

The adhesion between the redistribution layer 705 and the elastic dielectric layer 706 is poor such that the dielectric layer 706 will be deformed when external force applied (refer to arrow) during high temperature condition shown in FIG. 8, and thereby the redistribution layer 705 may be slightly peel from the surface of the elastic dielectric layer 706. It is noted that the deformation ratio of the dielectric layer 706 may be determined by the thickness of the elastic dielectric layer 706. No electrical fail may be expected owing to slightly peeling of the redistribution layer 705. Therefore, the life time of the package structure of the present invention will be increased, especially, when the solder ball is far away from the bonding pad.

Hence, according to the present invention, the aforementioned package structure has the advantages list as follow: the chip size package or wafer level package structure of the present invention can avoid open circuit of the solder ball cracking generated by reinforcing stress due to temperature variation or applied force after the solder balls solder joined on the print circuit board. Moreover, it does not need an additional material to intensify the solder ball.

Although specific embodiments have been illustrated and described, it will be obvious to those skilled in the art that various modifications may be made without departing from what is intended to be limited solely by the appended claims.

What is claimed is:

1. A structure of package, comprising:
build up layers made of elastic dielectric layers; and
conductive layer configured with said build up layers and coupled to a chip;
wherein said conductive layer is formed by employing lower power in sputtering seed metal layer process to gain a poor adhesion between said conductive layer and said elastic dielectric layer than that between said conductive layer and solder balls.

2. The structure in claim 1, wherein power density in said sputtering seed metal layer process is from 0.1 kW to 0.5 kW for pre-etching and from 1 kW to 4 kW for sputtering seed metal.

3. The structure in claim 1, wherein said elastic dielectric layer has the properties of CTE greater than 100 (ppm/° C.) and elongation above 30%.

4. The structure in claim 1, wherein said elastic dielectric layer has the properties of CTE greater than 100 (ppm/° C.) and elongation about 30%˜50%.

5. The structure in claim 1, wherein said elastic dielectric layer has deformation ratio about 30% to 50%.

6. The structure in claim 1, wherein said elastic dielectric layers comprise multiple silicone based dielectric layers.

7. The structure in claim 1, wherein thickness of said elastic dielectric layers under said conductive layer is above 3 micron.

8. The structure in claim 1, wherein thickness of said elastic dielectric layers on said conductive layer is about 10-50 micron.

9. The structure in claim 1, wherein said conductive layer comprises redistribution metal layer.

10. The structure in claim 9, wherein thickness of said redistribution metal layer is above 5 micron.

11. The structure in claim 9, wherein thickness of said redistribution metal layer is about from 10 to 15 micron.

12. The structure in claim 9, wherein said redistribution metal layer includes Ti/Cu/Au alloy or Ti/Cu/Ni/Au alloy.

13. The structure in claim 1, wherein said conductive layer comprises inter-connecting metal layer.

14. The structure in claim 1, wherein the thickness of said conductive layer is above 5 micron.

15. The structure in claim 1, further comprising a print circuit board coupled to said solder balls.

16. The structure in claim 1, further comprising an adhesive layer surrounding said chip.

17. The structure in claim 16, further comprising a rigid substrate which said adhesive layer and said chip are formed on said rigid substrate,
